(19) United States
(12) Patent Application Publication
(10) Pub. No.: US 2013/0070421 A1
(43) Pub. Date: Mar. 21, 2013

(54) ANTI-SAG APPARATUS FOR EXPANSION CARDS

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/280,355

(22) Filed: Oct. 25, 2011

(30) Foreign Application Priority Data
Sep. 19, 2011 (CN) 201110277751.4

(51) Int. Cl. H05K 7/14

(52) U.S. Cl. 361/724

(57) ABSTRACT

An anti-sag apparatus is mounted in a chassis for supporting an expansion card. The anti-sag apparatus includes a fixing bracket, a mounting member, and a supporting module. The mounting member defines a slide slot and a positioning hole communicating with the slide slot. The supporting module includes a supporting member, a manipulation member, and a resilient element arranged between the supporting member and the manipulation member. The manipulation member includes a pole forming a neck able to slide through the slide slot, and a locking portion sized to be stopped from entering the slide slot. When the pole is placed in the positioning hole, the supporting member supports the expansion card. When the pole is driven to slide along the slide slot, the supporting member disengages from the expansion card.

### BACKGROUND

1. Technical Field

The present disclosure relates to an anti-sag apparatus for an expansion card.

2. Description of Related Art

An expansion card is mounted in a chassis with a first end of the expansion end fixed to the chassis while a second end of the expansion card is cantilevered. As a result, when the expansion card is long and horizontally fixed to the chassis, the second end of the expansion card may sag and contact an electronic unit below the expansion card, forming a short circuit.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an anti-sag apparatus, a chassis, and an expansion card, wherein the anti-sag apparatus includes a fixing bracket, a mounting member, and a supporting module.

FIG. 2 is an enlarged view of the encircled portion II of FIG. 1.

FIG. 3 is an enlarged view of the supporting module of FIG. 1, but shown in a different perspective.

FIG. 4 is an assembled view of FIG. 1.

FIG. 5 is an enlarged view of the encircled portion V of FIG. 4.

FIGS. 6 to 8 are partially cutaway views of FIG. 5, showing the supporting module in different states.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

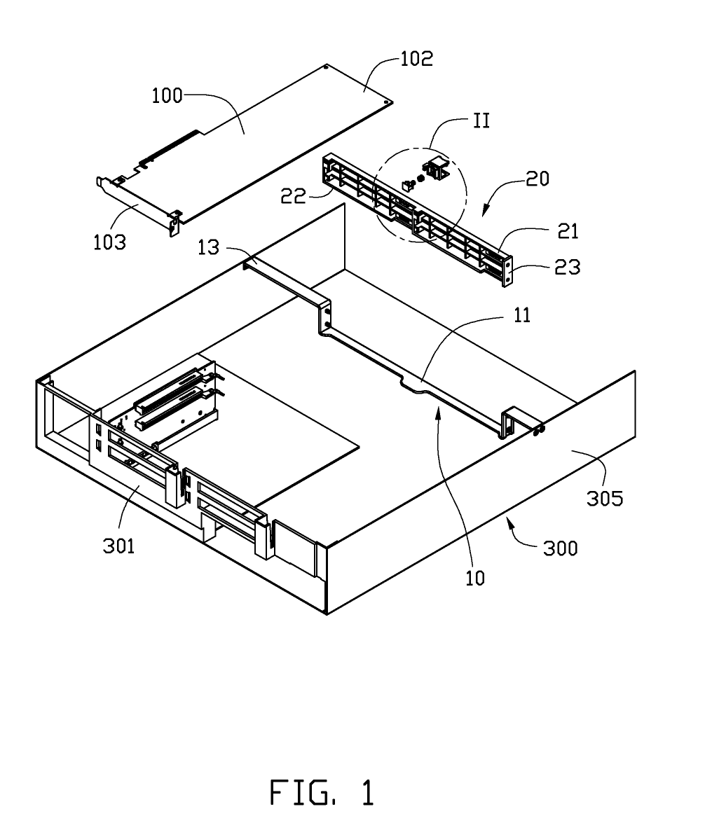

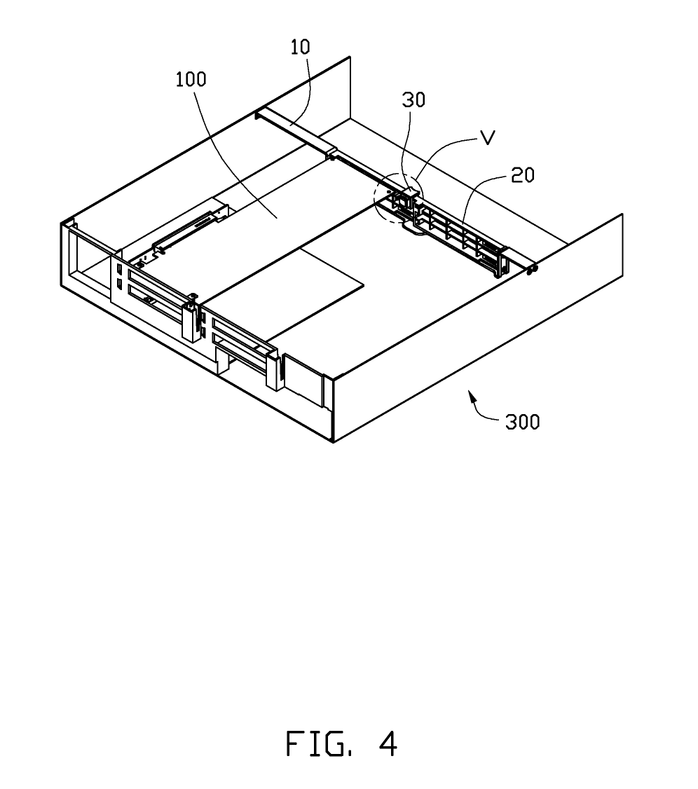

Referring to FIG. 1 and FIG. 4, in an exemplary embodiment, an anti-sag apparatus is mounted in a chassis 300 to support an expansion card 100 horizontally arranged in the chassis 300. A fixing plate 103 is mounted to a first end of the expansion card 100, to be fixed to a sidewall 301 of the chassis 300.

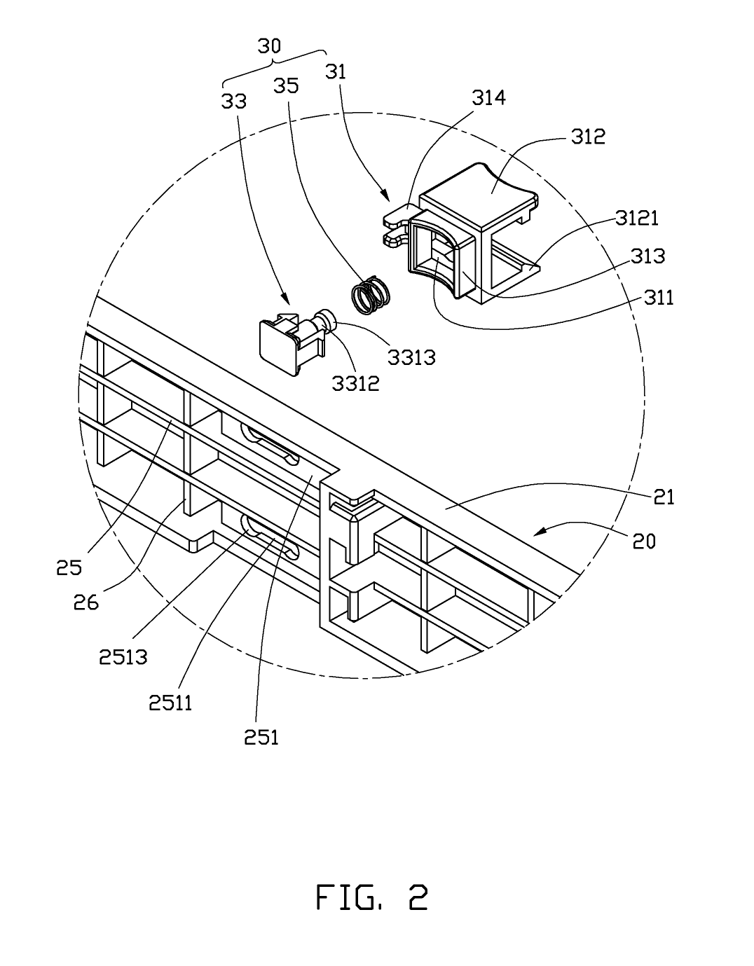

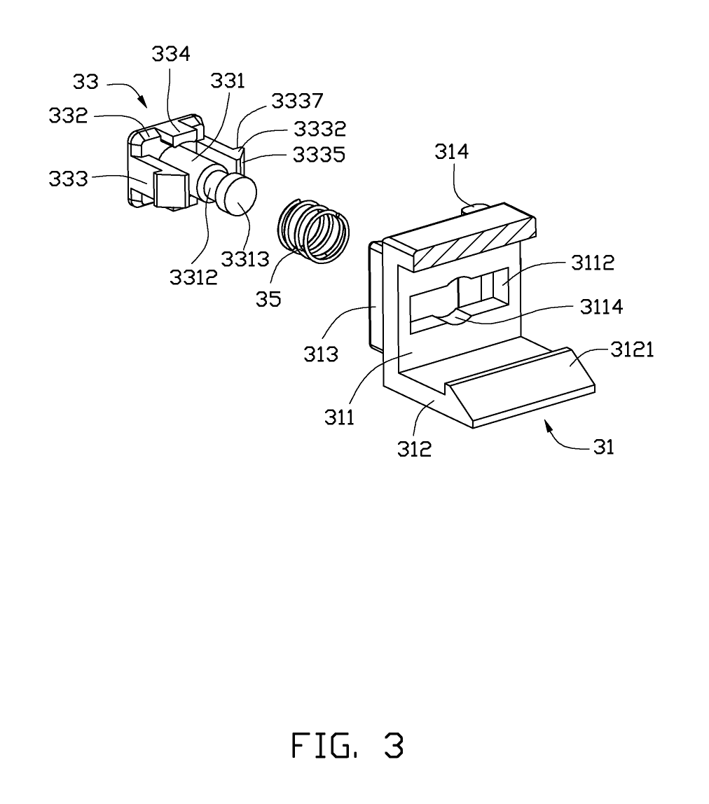

Referring to FIGS. 1 to 3, the anti-sag apparatus includes a fixing bracket 10, a mounting member 20, and a supporting module 30.

The fixing bracket 10 includes a substantially U-shaped receiving portion 11 parallel to the sidewall 301, and two fixing arms 13 extending out from opposite top ends of the receiving portion 11 away from each other. In one embodiment, the fixing arms 13 are fixed to opposite sidewalls 305 of the chassis 300 extending from opposite ends of the sidewall 301 with screws.

In one embodiment, the mounting member 20 is a rectangular frame, including a top wall 21, a bottom wall 22, and two end walls 23 connecting corresponding ends of the top and bottom walls 21 and 22. The mounting member 20 further includes a plurality of first strips 25 arranged between and parallel to the top and bottom walls 21 and 22, and a plurality of second strips 26 arranged between and parallel to the end walls 23 and intersecting with the first strips 25. The mounting member 20 further forms a plurality of positioning portions 251. Some of the positioning portions 251 are connected between the top wall 21 and the corresponding first strip 25 adjacent to top wall 21. Other positioning portions 251 are connected between the bottom wall 22 and the corresponding first strip 25 adjacent to the bottom wall 22. Each of the positioning portions 251 defines a slide slot 2511, and two round positioning holes 2513 communicated with and arranged at opposite ends of the slide slot 2511. A diameter of each of the positioning holes 2513 is greater than a width of the slide slot 2511.

The supporting module 30 includes a supporting member 31, a manipulation member 33, and a resilient member 35.

The supporting member 31 includes a base plate 311, two holding arms 312 perpendicularly extending rearward from top and bottom sides of the base plate 311, a substantially rectangular accommodating frame 313 protrudes from a front side of the base plate 311 opposite to the holding arms 312, and two supporting tabs 314 parallel to the holding arms 312 and extending from a side of the accommodating frame 313. The base plate 311 defines a slot 3112 extending through the base plate 311. Opposite recesses 3114 are defined in centers of top and bottom sides bounding the slot 3112, and cooperatively bound an access 3115 in a middle of the slot 3112. A hook 3121 is formed on a distal end of each of the holding arms 312 toward the other holding arm 312. An inner surface of the accommodating frame 31 communicates with the slide slot 3112. A space between two supporting tabs 314 is just large enough to receive a second end 102 of the expansion card 100.

The manipulation member 33 includes a substantially rectangular manipulation portion 332, a cylindrical pole 331 extending from a center of the manipulation portion 332, two engagement arms 333 extending from two opposite sides of the manipulation portion 332 and parallel to the pole 331, and two stop portions 334 extending the other two opposite sides of the manipulation portion 332 and parallel to the pole 331. The pole 331 defines an annular groove in the circumference of the pole 331 adjacent to a distal end of the pole 331 opposite to the manipulation portion 332 to from a neck 3312. Therefore, a locking portion 3313 is formed on the distal end of the pole 331. A diameter of the neck 3312 is less than the width of each of the slide slots 2511. A diameter of the locking portion 3313 is greater than the width of each of the slide slots 2511, but less than the diameter of each of the positioning holes 2513. A hook 3332 protrudes from a side of each of the engagement arms 333 opposite to the pole 331, adjacent to a distal end of the engagement arm 333. The hook 3332 includes a slope 3335 opposite to the manipulation portion 332, and a stop surface 3337 substantially perpendicular to the axial direction of the pole 331 and facing the manipulation portion 332.

In one embodiment, the resilient member 35 is a coil spring.

In assembly, the mounting member 20 is received in the receiving portion 11, and is fixed to the fixing bracket 10 by screwing.

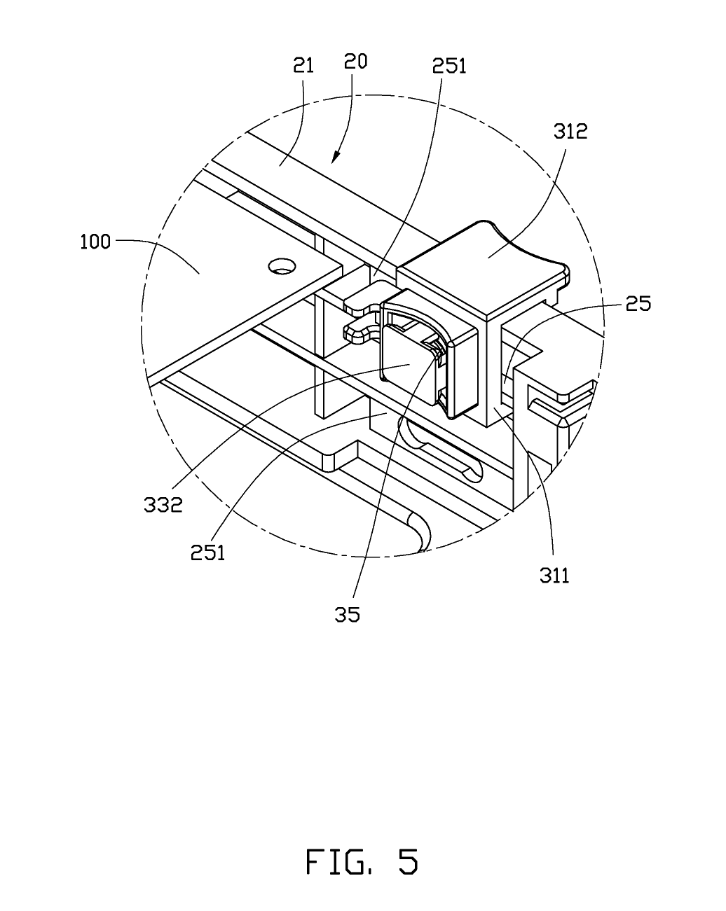

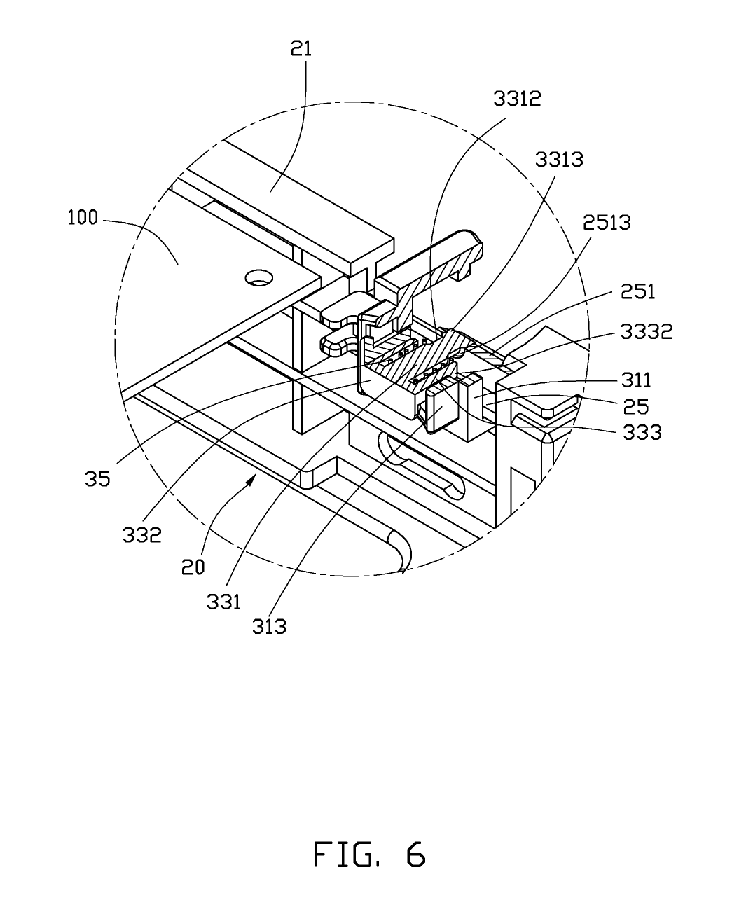

Referring to FIGS. 5 and 6, the supporting module 30 is mounted to one of the positioning portions 251. The holding arms 312 are slidably engaged with the top wall 21 and the corresponding first strip 25. Therefore, the supporting member 31 is slidably mounted to the mounting member 20, with the access 3115 aligned with one of the positioning holes 2513 (adjacent to a right end of the positioning portion 251 in FIG. 6). The resilient member 35 is placed around the pole 331. The manipulation member 33 extends the accommodating frame 313. The hooks 3332 abut against opposite sides of the frame 313 in the slot 3112, thereby preventing the manipulation member 33 from disengaging from the support member 31. Opposite ends of the resilient member 35 respectively abut against the base plate 311 and the manipulation portion 332. The pole 331 extends through the access 3115 and the positioning hole 2513.

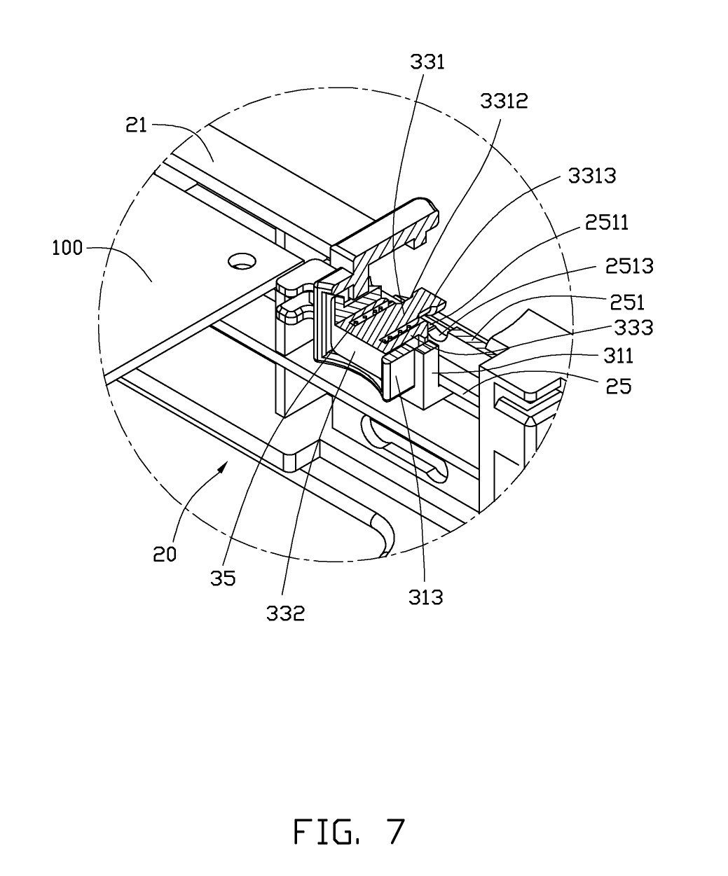

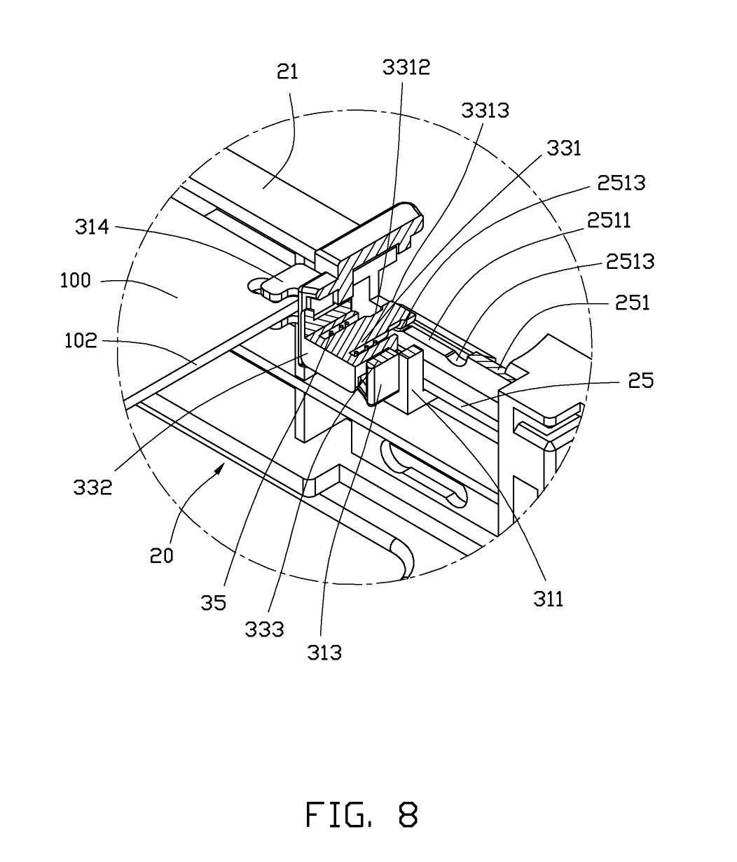

Referring to FIGS. 6 to 8, to mount the expansion card 100 to the chassis 300, the fixing plate 103 is fixed to the sidewall 301. The manipulation portion 332 is pressed the positioning portion 251, to deform the resilient member 35. The pole 331 is slid in the recess 3114 and the positioning hole 2513 to an unlocked position, where the neck 3312 is accommodated in the slide slot 2511. Since the diameter of the neck 3312 is less than the width of the slide slot 2511, the pole 331 is enabled to slide away from the positioning hole 2513, into the slide slot 2511. The supporting module 30 is slid towards the expansion card 100 with the pole 331 sliding in the slide slot 2511. When the neck 3312 enters the positioning hole 2511 adjacent to the expansion card 100, the second end of the expansion card 100 opposite to the fixing plate 103 is sandwiched between the supporting tabs 314. Therefore, the expansion card 100 is prevented from sagging. After releasing the manipulation portion 332, the resilient member 35 is restored to drive the manipulation portion 332 to move away from the positioning portion 251, therefore, the pole 331 is slid to a locked position, where the locking portion 3313 is placed in the positioning hole 2513. Since the diameter of the locking portion 3313 is greater than the width of the slide slot 2511, the pole 331 is prevented from sliding away from the expansion card 100, and the supporting tabs 314 are kept clipping the expansion card 100.

To release the supporting module 30 from the expansion card 100, the manipulation portion 332 is pressed toward the positioning portion 251. The pole 331 is slid to the unlocked position. The manipulation module 30 is driven to slide away from the expansion card 100, thereby releasing the expansion card 100.

In other embodiments, the anti-sag apparatus may include more than one supporting module 30 mounted to the corresponding positioning portions 251 for supporting more than one expansion card.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiments.

What is claimed is:

1. An anti-sag apparatus for an expansion card mounted in a chassis, the anti-sag apparatus comprising:
a mounting member fixed to the chassis, and comprising a positioning portion, the positioning portion defining a long slide slot and a positioning hole communicating with the slide slot; and
a supporting module comprising:
a supporting member coupled to the mounting member and slidable along the slide slot; and
a manipulation member mounted to the supporting member, and comprising a pole extending through the supporting member, the pole forming a neck adjacent to a distal end of the pole and a locking portion at the distal end; the locking portion being sized to be stopped from entering the slide slot of the mounting member; the neck being sized to slide in the slide slot;
wherein the supporting member supports the expansion card in response to the pole being slid into the positioning hole of the mounting member, the manipulation member is movable between a locked position, where the locking portion of the pole is received in the positioning hole of mounting member, and an unlocked position, where the neck of the pole is received in the positioning hole, thereby being aligned with the slide slot of the mounting member.

2. The anti-sag apparatus of claim 1, wherein the supporting module further comprises a resilient member connected between the supporting member and the manipulation member, to bias the manipulation member to the locked position.

3. The anti-sag apparatus of claim 1, wherein the supporting member comprises two parallel supporting tabs to sandwich the expansion card between the supporting tabs in response to the locking portion of the pole being positioned in the positioning hole of the mounting member.

4. The anti-sag apparatus of claim 1, wherein the mounting member comprises a top wall, a bottom wall, and a plurality of strips arranged between and parallel to the top and bottom walls, the positioning portion is connected between the top wall and a neighboring strip, the supporting member comprises a base plate and opposite holding arms extending from the base plate and respectively slidably engaged with the top wall and the neighboring strip, the base plate defines a slot, through which the pole extends.

5. The anti-sag apparatus of claim 4, wherein the manipulation member comprises a manipulation portion, the pole extends from the manipulation portion, the resilient member is a coil spring plated around the pole, opposite ends of the resilient member respectively abut against the manipulation portion and the base plate of the supporting member.

6. The anti-sag apparatus of claim 5, wherein the supporting member further comprises an accommodating frame protruding from the base plate opposite to the holding arms, the manipulation member further comprises two engagement arms extending from the manipulation portion to engage with the frame.

7. The anti-sag apparatus of claim 4, further comprising a fixing bracket defining a receiving portion, wherein the mounting member is securely received in the receiving portion of the fixing bracket.

8. A device, comprising:
a chassis comprising a first sidewall, and two second sidewalls extending from opposite ends of the first sidewall;
an expansion card comprising a first end fixed to the first sidewall, and a second end opposite to the first end;
a mounting member mounted between the second sidewalls and opposite to the first sidewall, the mounting member comprising a positioning portion, the positioning portion defining a long slide slot and a positioning hole communicating with the slide slot; and
a supporting module comprising:
a supporting member slidably coupled to the mounting member along a longitudinal direction of the slide slot; and
a manipulation member mounted to the supporting member, and comprising a pole extending through the supporting member, the pole forming a small neck adjacent to a distal end of the pole and a great locking portion at the distal end; the locking portion being sized to enter the positioning hole but to be prevented entering the slide slot, thereby allowing the supporting member to position the second end of the expansion card;
the neck being sized to slide in the slide slot, thereby allowing the supporting member disengaging from the second end of the expansion card.

9. The device of claim 8, wherein the supporting module further comprises a resilient member connected between the supporting member and the manipulation member, to bias the locking portion of the pole to withdraw into the positioning hole.

10. The device of claim 8, wherein the supporting member comprises two parallel supporting tabs to sandwich the expansion card between the supporting tabs.

11. The device of claim 8, wherein the mounting member comprises a top wall, a bottom wall, and a strip arranged between and parallel to the top and bottom walls, the positioning portion is connected between the top wall and the strip, the supporting member comprises a base plate and opposite holding arms extending from the base plate and respectively slidably engaged with the top wall and the strip, the base plate defines a slot, through which the pole extends.

12. The device of claim 11, wherein the manipulation member comprises a manipulation portion, the pole extends from the manipulation portion, the resilient member is a coil spring plated around the pole, opposite ends of the resilient member respectively abut against the manipulation portion and the base plate of the supporting member.

13. The device of claim 12, wherein the supporting member further comprises an accommodating frame protruding from the base plate opposite to the holding arms, the manipulation member further comprises two engagement arms extending from the manipulation portion to engage with the frame.

14. The device of claim 11, further comprising a fixing bracket defining a receiving portion, wherein the fixing bracket is connected between the second sidewalls and opposite to the first sidewall, the mounting member is securely received in the receiving portion.
